(19) United States
(12) Patent Application Publication
(10) Pub. No.: US 2020/0064918 A1
(43) Pub. Date: Feb. 27, 2020

(54) CAPACITIVE FLEX SENSORS

(71) Applicant: Microchip Technology Incorporated, Chandler, AZ (US)

(72) Inventor: Keith Edwin Curtis, Queen Creek, AZ (US)

(73) Assignee: Microchip Technology Incorporated, Chandler, AZ (US)

(21) Appl. No.: 16/246,579

(22) Filed: Jan. 14, 2019

Related U.S. Application Data
(60) Provisional application No. 62/720,401, filed on Aug. 21, 2018.

(51) Int. Cl. G06F 3/01; H03K 17/975; H03K 17/96; G01L 1/14

(52) U.S. Cl. CPC G06F 3/014; H03K 17/975; G01L 1/146; H03K 17/962; G06F 3/016

(57) ABSTRACT

A capacitive flex sensor comprises a first capacitor plate disposed on a first surface of a flexible insulated substrate and a second capacitor plate is provided on a second surface of the flexible substrate. The flexible substrate is adapted to be a compressible and stretchable dielectric between the first and second capacitor plates. A plurality of these capacitive flex sensors are positioned on the flexible substrate, e.g., a glove, that may be adapted to conform to a body part having flexure points. A preferred body part is a hand/fingers and the capacitive flex sensors may be located proximate to movable joints of the hand/fingers. Movement (flexing) of a joint may cause the physical structure of the capacitive flex sensor to be depressed or deformed. This causes the dielectric thickness and/or plate area to change, thus changing the capacitance value of the flex sensor located proximate to the joint being flexed.

### RELATED PATENT APPLICATION

This application claims priority to commonly owned U.S. Provisional Patent Application Ser. No. 62/720,401; filed Aug. 21, 2018; entitled “Physical Force Touch Capacitive Flex Sensor,” by Keith Edwin Curtis; and is hereby incorporated by reference herein for all purposes.

### TECHNICAL FIELD

The present disclosure relates to flex sensors and, more particularly, to capacitive flex sensors.

### BACKGROUND

Flex sensors may be used to input information about the movement of a user's fingers, hands, arms and/or legs. Current technology flex sensors rely on pressure sensitive resistive ink and must be physically integrated with an attachment device that conforms to a body part, e.g., glove over a hand of a user. The output of the pressure sensitive resistive ink flex sensor is a resistance based upon total flexing of the sensor structure. These flex sensors are somewhat flexible but do require effort to flex them. Therefore, these resistive ink flex sensors have some resistance to flexing, thereby diminishing movement sensitivity.

Construction of the flex sensors are accomplished by a number of manufacturing methods but are time consuming and costly. The current technology approach sews pre-built flex sensors onto the gloves and mounts monitoring electronics therewith. The glove must be individually sized for each user, and if damaged the entire glove and sensors must be discarded. The cost of manufacturing the gloves is also high due to the complex methods required for attaching the sensors and wiring them to the electronics. Typically, only about 10 flex sensors can be cost effectively implemented onto the attachment device, and fine details required for finger joints are often sacrificed for cost savings.

### SUMMARY

Therefore, what is needed is a simpler, more cost-effective implementation of flex sensors, preferably able to reuse the electronics if the glove is damage, and easily adapted to fit different size requirements.

According to an embodiment, an apparatus for detecting flex position changes may comprise: a flexible non-conductive substrate having a thickness; a plurality of conductive plates proximate to a first surface of the flexible non-conductive substrate and located selectively thereon; and a plurality of first electrical connections coupled to respective ones of the plurality of conductive plates, wherein when a flex force may be applied to an area proximate to at least one of the plurality of conductive plates at least one of: the thickness of the flexible non-conductive substrate at the flex force application area may change; and an area of at least one of the plurality of conductive plates may change.

According to a further embodiment, may comprise: a second electrical connection adapted for coupling to a conductive surface proximate to a second surface of the flexible non-conductive substrate; wherein the conductive surface, the flexible non-conductive substrate and the plurality of conductive plates form a plurality of capacitive flex sensors, and wherein each of said plurality of capacitive flex sensors comprises a capacitor having a capacitance and when the flex force may be applied to the area proximate to at least one of the plurality of conductive plates, the capacitance of the respective capacitive flex sensor changes.

According to a further embodiment, when the flex force may be applied to the area proximate to at least one of the plurality of conductive plates the flexible non-conductive substrate thickness decreases at the flex force application area. According to a further embodiment, when the flex force may be applied to the area proximate to at least one of the plurality of conductive plates the flexible non-conductive substrate stretches at the flex force application area, whereby an area of at least one of the plurality of conductive plates proximate to the flex force application area increases.

According to a further embodiment, the conductive surface may be skin of a user. According to a further embodiment, the flexible non-conductive substrate may be shaped to conform to a body part. According to a further embodiment, the flex force may be a change in position of the body part. According to a further embodiment, a capacitance measurement circuit may be provided for measuring capacitance of each of the plurality of capacitive flex sensors. According to a further embodiment, a microcontroller may be provided for storing and processing the measured capacitances of the plurality of capacitive flex sensors. According to a further embodiment, the measured capacitances of the plurality of flex sensors associated with each of the plurality of conductive plates may be correlated with the respective flex forces applied at the respective flex force application areas.

According to a further embodiment, the flex forces applied may be from movements of the flexible non-conductive substrate to areas at each of the plurality of capacitive flex sensors. According to a further embodiment, a skin surface on a user hand may be the conductive surface and the flexible non-conductive substrate may be shaped into a glove that the user hand fits therein. According to a further embodiment, the flex forces applied may be displacements of the flexible non-conductive substrate by changes in angular positions of at least one portion of the user hand inside of the glove. According to a further embodiment, the at least one portion of the user hand may be selected from the group consisting of a finger joint, a thumb joint, a knuckle and a wrist. According to a further embodiment, the conductive surface may be deposed on the second surface of the flexible substrate. According to a further embodiment, a conductive shield insulated from and over the plurality of conductive plates may be provided.

According to another embodiment, a method for detecting flex position changes at a plurality of locations may comprise the steps of: providing a flexible non-conductive substrate having a thickness; providing a plurality of conductive plates proximate to a first surface of the flexible non-conductive substrate and located selectively thereon; providing a conductive surface proximate to a second surface of the flexible non-conductive substrate; coupling a plurality of first electrical connections to respective ones of the plurality of conductive plates; providing a plurality of capacitive flex sensors with the conductive surface, the flexible non-conductive substrate and the plurality of conductive plates, wherein each of said plurality of capacitive flex sensors has a capacitance; and measuring the capacitance of each of the plurality of capacitive flex sensors.

According to a further embodiment of the method, may comprise the step of applying at least one force to at least one area proximate to at least one of said plurality of capacitive flex sensors, whereby at least one capacitance thereof changes. According to a further embodiment of the method, may comprise the step of correlating the measured capacitances of the plurality of capacitive flex sensors with flex forces applied to each of the areas proximate thereto. According to a further embodiment of the method, the flex forces applied may represent angular position changes to areas proximate to any one or more of said plurality of capacitive flex sensors. According to a further embodiment of the method, may comprise the step of detecting changes in the measured capacitances. According to a further embodiment of the method, may comprise the step of determining changes in the capacitances of each of said plurality of capacitive flex sensors when the flex forces may be applied thereto.

### BRIEF DESCRIPTION OF THE DRAWINGS

A more complete understanding of the present disclosure may be acquired by referring to the following description taken in conjunction with the accompanying drawings wherein:

FIG. 1 illustrates a schematic diagram of the flex areas on a human hand, according to the teachings of the present disclosure;

FIG. 2 illustrates a schematic diagram of the compression points on a human hand when closed, according to the teachings of the present disclosure;

FIG. 3 illustrates a schematic diagram of the forces acting upon a capacitive flex sensor during typical applications, according to specific example embodiments of this disclosure;

FIG. 4 illustrates a schematic diagram of forces that may cause deformation of the capacitive flex sensor during actuation, according to specific example embodiments of this disclosure; and

FIG. 5 illustrates a schematic diagram of a circuit for interfacing with the plurality of capacitive flex sensors mounted on a device used for attaching the capacitive flex sensors to a portion of a user's body, according to specific example embodiments of this disclosure;

FIG. 6 illustrates a schematic block diagram of an electronic interface for the plurality of capacitive flex sensors shown in FIG. 5, according to specific example embodiments of this disclosure; and

FIG. 7 illustrates a schematic flow diagram of the operation of capacitive flex sensors, according to specific example embodiments of this disclosure.

While the present disclosure is susceptible to various modifications and alternative forms, specific example embodiments thereof have been shown in the drawings and are herein described in detail. It should be understood, however, that the description herein of specific example embodiments is not intended to limit the disclosure to the forms disclosed herein.

### DETAILED DESCRIPTION

Embodiments of the present disclosure may include, for a virtual reality interface, movement sensors for a user's fingers, hands, feet, neck and arms. These movement sensors may comprise capacitive flex sensors whose capacitance changes when its structure is physically depressed, elongated and/or deformed. Depressed, elongated and deformed will be used interchangeably herein.

According to specific example embodiments of this disclosure, the capacitance of the capacitive flex sensor changes when a force is applied thereto. The force causes the thickness of a flexible dielectric substrate located between capacitor plates, and/or plate area of the capacitor plate(s) to change, thus changing the capacitance value thereof. As an example, the capacitance C of a capacitor constructed of two parallel plates, each having an area A and separated by a distance d, is represented by the formula: C=εᵣε₀(A/d), where εᵣ is the dielectric constant of the material between the plates and ε₀ is the electric constant. If area A is made larger or distance d between plates smaller, then the capacitance C will increase. The human body is mainly water with an εᵣ of over 80, thus making a good conductive surface for a capacitor plate.

The capacitive flex sensor plates may be attached to a surface of insulating material (dielectric substrate), e.g., a glove, and the glove may be placed over the user's hand. The user's skin may then act as a ground plane or common capacitor plate for all of the flex sensors, wherein the ground plane acts as one capacitor plate and the sensor plate the other capacitor plate with a deformable dielectric (glove material) therebetween. The user's hand (skin) may be coupled to ground (common) connection at some point in the glove when placed over the hand of the user. When the user flexes an individual joint, the result is a longitudinal stretching of the glove surface (dielectric substrate) and/or compression at the location of the joint flexure, which may result in a thinning or compression of the glove material (dielectric substrate) over the flexed joint, thereby causing a measurable change in the capacitance of the capacitive flex sensor at that flexed joint. Alternatively, a conductive coating placed on the opposite side (inside surface) of the glove may be used as the common ground plan (plate) or a plurality of ground plates of about the same size and locations as the sensor (top) plate and coupled together, thereby eliminating the necessity of requiring electrical coupling to the skin of a user's hand.

Only one electrical contact need be bonded to the glove and this can be accomplished by, for example but is not limited to, either printing silver bearing ink onto the inner part of the glove or weaving conductive materials into the glove. Requiring separately manufactured sensors that have to be individually attached to the surface of a glove is thus eliminated, thereby reducing costs and allowing more sensors to be used, resulting in more accurate movement detection. The cost of adding an electrically conductive plate of a capacitor comprising the flex sensor is also reduced as it may be added through printing on an outer layer of the glove. Preferably, the glove, with its printed conductive sensor plates, would be disposable with the sensing electronics detachable from these sensor plates for transfer to a new glove/sensor plates or a new size glove/sensor plates for a different user.

The outside of the glove may be screened, e.g., using silver bearing ink, to create a plurality of capacitive flex sensor plates over each of the flexure points (user joints). Monitoring electronics may then be attached to the glove using conductive adhesive for making electrical contact with each of the capacitive flex sensor plates. A separate conductive electrode contact may be held against the user's skin to make the ground (common plate) connection for the capacitive flex sensors. Alternately, the inside of the glove may have a conductive coating that provides for a common (ground) plate(s) of the sensor capacitors. Once worn by the user, the user may perform a simple joint flexing sequence to calibrate the electronics to the glove and the user.

Embodiments of the present disclosure may also be adapted for detecting movement in other parts of a person's body, e.g., knee, leg, hip, foot, arm, elbow, wrist, neck, torso, without limitation, and may be used in combination with signal processing for detection of unusual movements or non-movements, e.g., Parkinson's, epilepsy, cessation of breathing, without limitation. These capacitive flex sensors may also be used for inexpensive feedback detection of limb movement under artificial stimulation such as when controlling a paraplegic's leg muscles during electric stimulations thereof.

A conductive shield may be placed over (e.g., over the opposite side of the conductive plates of the capacitive flex sensor from the common/ground plate) conductive plates of the capacitive flex sensors and may be at substantially the same voltage as the conductive plates of the capacitive flex sensors. This will reduce the impact of external electric fields affecting operation of the capacitive physical force sensors.

Referring now to the drawings, the details of example embodiments are schematically illustrated. Like elements in the drawings will be represented by like numbers, and similar elements will be represented by like numbers with a different lower-case letter suffix.

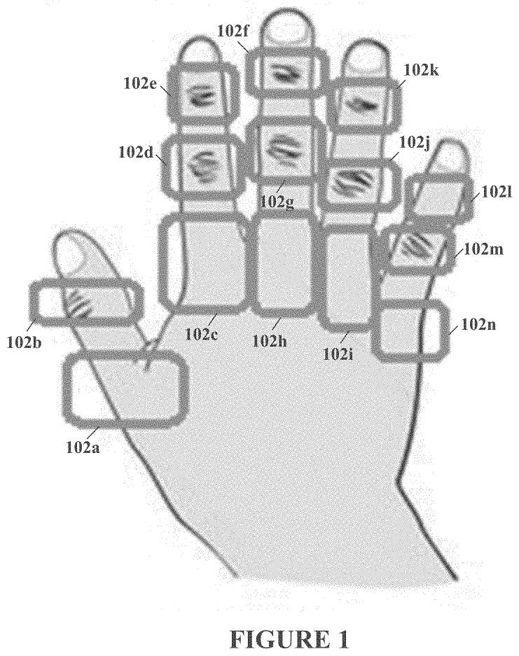

Referring to FIG. 1, depicted is a schematic diagram of the flex areas on a human hand, according to the teachings of the present disclosure. The joints of the hand make good flex points for applying force to the areas of the capacitive flex sensors. This force may cause the structure of the capacitive flex sensor to change, e.g., reduce the dielectric substrate thickness and/or increase the area of the sensor capacitor plate due to stretching of the dielectric substrate, both resulting in an increase of the capacitance value thereof. The amount of force applied to a capacitive flex sensor may vary depending upon the angle (amount) of flexing of the joint. Thus, a range of capacitance values may be obtained in proportion to the angle (amount) of flexing of the joint. Calibration of the joint positions (angles) may be correlated with the corresponding capacitance values of the capacitive flex sensors

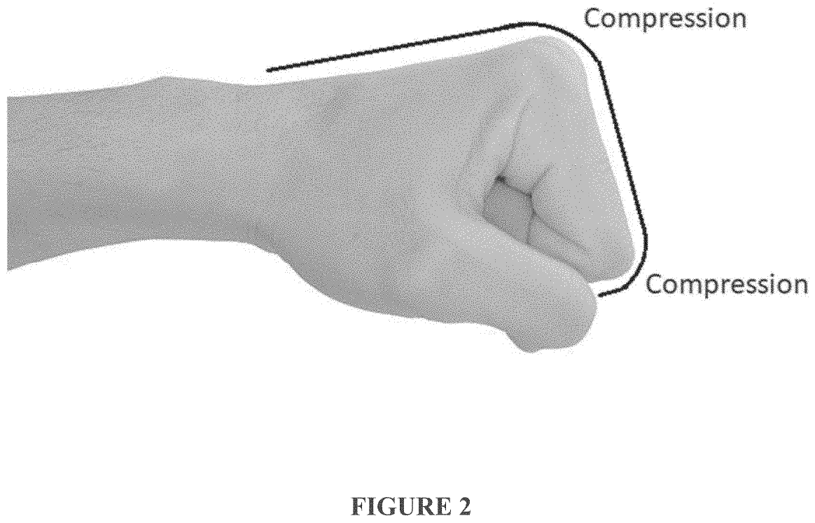

Referring to FIG. 2, depicted is a schematic diagram of the compression points on a human hand when closed, according to the teachings of the present disclosure. As shown in FIG. 2, pressure points at the knuckle and first finger joints apply compressive pressure at the corresponding points where the capacitive flex sensors are located. As indicated above, each of the sensor capacitors may be defined by the locations of the capacitor plates placed on the deformable dielectric. The amount of compressive force may be proportional the joint angle flexure.

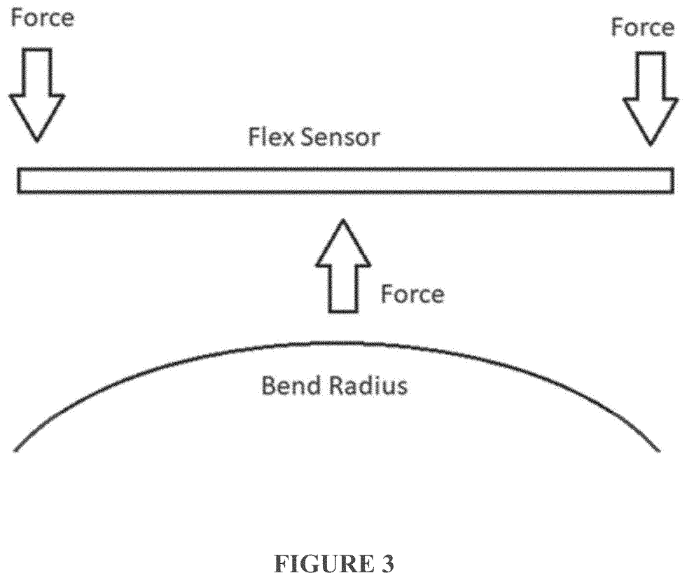

Referring to FIG. 3, depicted is a schematic diagram of the forces acting upon a capacitive flex sensor during typical applications, according to specific example embodiments of this disclosure. A force at the bend radius will be created thereby causing that area to compress and cause the dielectric thickness (d) to decrease, thus increasing the capacitance of the capacitive flex sensor at that location.

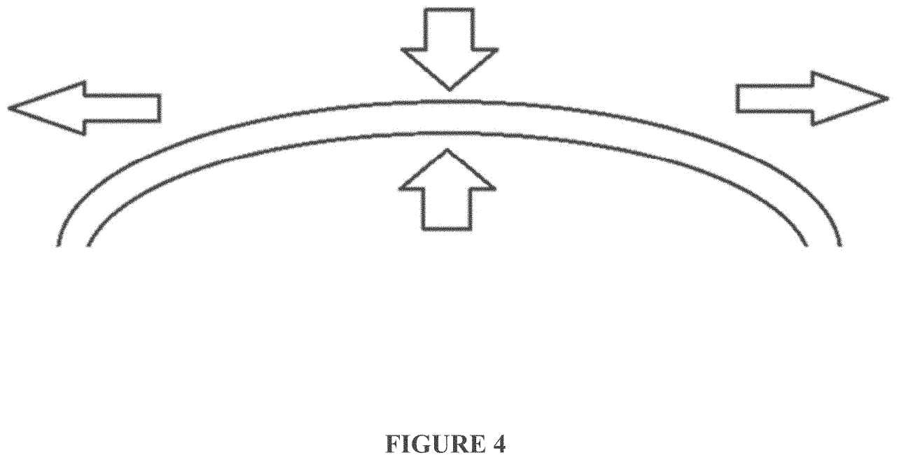

Referring to FIG. 4, depicted is a schematic diagram of forces that may cause deformation of the capacitive flex sensor during actuation, according to specific example embodiments of this disclosure. FIG. 4 shows stretching forces that may increase the area (A) of the capacitive flex sensor plate and/or reduce the dielectric thickness (d), thereby changing (increasing) the capacitance value of the respective capacitive flex sensor. Thus, when the joint flexes, the dielectric material (e.g., glove) stretches and thins out thereby moving the sensor plate closer to the user's skin (ground or skin plate). The stretching may also increase the area of the capacitive flex sensor plate, thereby increasing the capacitance thereof.

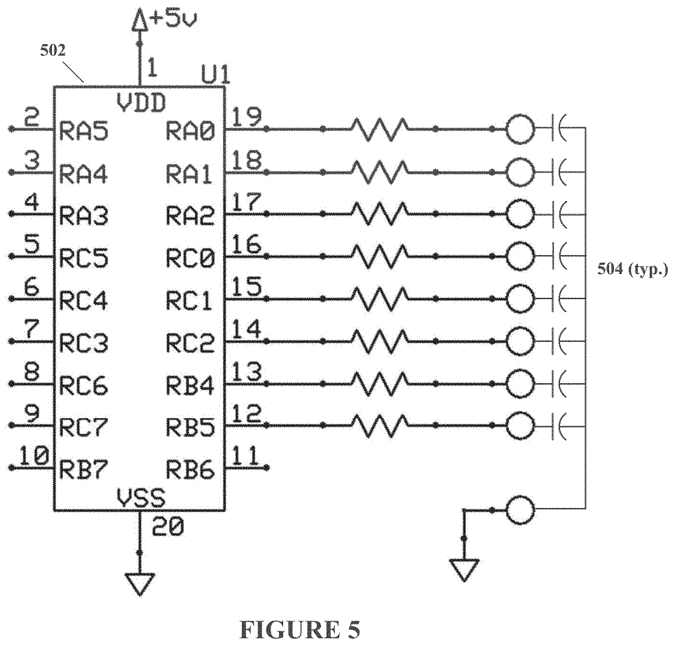

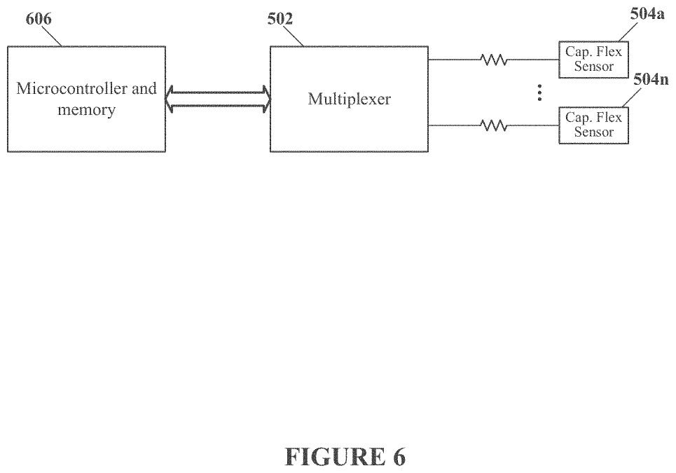

Referring to FIG. 5, depicted is a schematic diagram of a circuit for interfacing with the plurality of capacitive flex sensors mounted on a device used for attaching the capacitive flex sensors to a portion of a user's body, according to specific example embodiments of this disclosure. A multiplexer 502 may be used to couple each capacitive flex sensor 504 to the detection and processing electronics as shown in FIG. 6.

Referring to FIG. 6, depicted is a schematic block diagram of an electronic interface for the plurality of capacitive flex sensors shown in FIG. 5, according to specific example embodiments of this disclosure. A microcontroller 606 may be used to generate signal voltages on the plates of the capacitive flex sensors 504 and determine capacitances thereof. Capacitance determination of the sensors may be by capacitive voltage division (CVD), charge time measurement unit (CTMU), or other capacitance measuring techniques. These capacitance values may be stored in the microcontroller and memory 606 and used in determining flex inputs (e.g., joint angle positions) from the force producing device, e.g., user hand. Flex position information may be transmitted from the microcontroller 606 via wireless transmission, e.g., BlueTooth, WiFi, and the like.

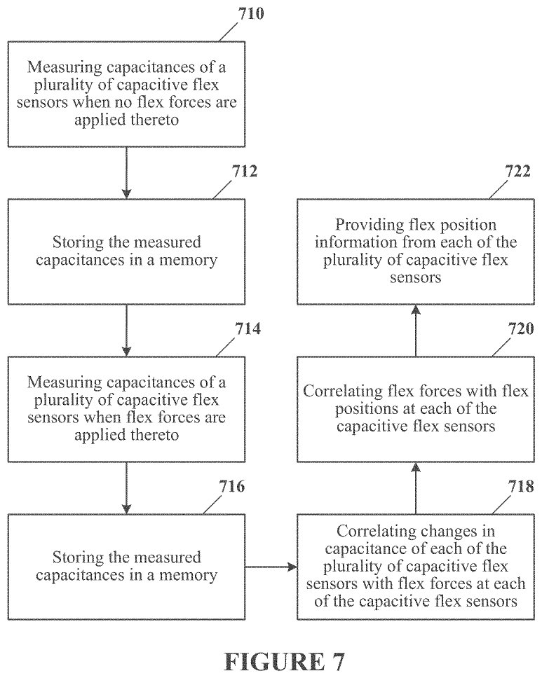

Referring to FIG. 7, depicted is a schematic flow diagram of the operation of capacitive flex sensors, according to specific example embodiments of this disclosure. In step 710 capacitances of each of the plurality of capacitive flex sensors 504 are measured with no flex forces applied to any of the areas proximate to the capacitive flex sensors 504. In step 712 these non-flex force capacitances may be stored in a memory, e.g., microcontroller and memory 606. In step 714 capacitances of each of the plurality of capacitive flex sensors 504 are measured with flex forces applied to areas proximate to the capacitive flex sensors 504. In step 716 these flex force capacitances may be stored in the memory, e.g., microcontroller and memory 606. In step 718 the stored capacitance changes may be correlated with respective flex forces. In step 720 the flex forces or stored capacitance changes may be correlated with associated flex positions at each of the capacitive flex sensors. In step 722 information about these flex positions may be provided for use by another application or process, e.g., video game control, tool operation, machine or device control and the like. Capacitance changes may be representative of flex position changes and may be used for calibration thereof.

The present disclosure has been described in terms of one or more embodiments, and it should be appreciated that many equivalents, alternatives, variations, and modifications, aside from those expressly stated, are possible and within the scope of the disclosure. While the present disclosure is susceptible to various modifications and alternative forms, specific example embodiments thereof have been shown in the drawings and are herein described in detail. It should be understood, however, that the description herein of specific example embodiments is not intended to limit the disclosure to the particular forms disclosed herein.

What is claimed is:

1. An apparatus for detecting flex position changes, comprising:
a flexible non-conductive substrate having a thickness;
a plurality of conductive plates proximate to a first surface of the flexible non-conductive substrate and located selectively thereon; and
a plurality of first electrical connections coupled to respective ones of the plurality of conductive plates,
wherein when a flex force is applied to an area proximate to at least one of the plurality of conductive plates at least one of:
the thickness of the flexible non-conductive substrate at the flex force application area changes; and
an area of at least one of the plurality of conductive plates changes.

2. The apparatus according to claim 1, further comprising:
a second electrical connection adapted for coupling to a conductive surface proximate to a second surface of the flexible non-conductive substrate;
wherein the conductive surface, the flexible non-conductive substrate and the plurality of conductive plates form a plurality of capacitive flex sensors, and
wherein each of said plurality of capacitive flex sensors comprises a capacitor having a capacitance and when the flex force is applied to the area proximate to at least one of the plurality of conductive plates, the capacitance of the respective capacitive flex sensor changes.

3. The apparatus according to claim 1, wherein when the flex force is applied to the area proximate to at least one of the plurality of conductive plates the flexible non-conductive substrate thickness decreases at the flex force application area.

4. The apparatus according to claim 1, wherein when the flex force is applied to the area proximate to at least one of the plurality of conductive plates the flexible non-conductive substrate stretches at the flex force application area, whereby an area of at least one of the plurality of conductive plates proximate to the flex force application area increases.

5. The apparatus according to claim 2, wherein the conductive surface is skin of a user.

6. The apparatus according to claim 1, wherein the flexible non-conductive substrate is shaped to conform to a body part.

7. The apparatus according to claim 6, wherein the flex force is a change in position of the body part.

8. The apparatus according to claim 2, further comprising a capacitance measurement circuit for measuring capacitance of each of the plurality of capacitive flex sensors.

9. The apparatus according to claim 8, further comprising a microcontroller for storing and processing the measured capacitances of the plurality of capacitive flex sensors.

10. The apparatus according to claim 8, wherein the measured capacitances of the plurality of flex sensors associated with each of the plurality of conductive plates are correlated with the respective flex forces applied at the respective flex force application areas.

11. The apparatus according to claim 2, wherein the flex forces applied are from movements of the flexible non-conductive substrate to areas at each of the plurality of capacitive flex sensors.

12. The apparatus according to claim 2, wherein a skin surface on a user hand is the conductive surface and the flexible non-conductive substrate is shaped into a glove that the user hand fits therein.

13. The apparatus according to claim 12, wherein the flex forces applied are displacements of the flexible non-conductive substrate by changes in angular positions of at least one portion of the user hand inside of the glove.

14. The apparatus according to claim 13, wherein the at least one portion of the user hand is selected from the group consisting of a finger joint, a thumb joint, a knuckle and a wrist.

15. The apparatus according to claim 2, wherein the conductive surface is deposed on the second surface of the flexible substrate.

16. The apparatus according to claim 1, further comprising a conductive shield insulated from and over the plurality of conductive plates.

17. A method for detecting flex position changes at a plurality of locations, said method comprising the steps of:
providing a flexible non-conductive substrate having a thickness;
providing a plurality of conductive plates proximate to a first surface of the flexible non-conductive substrate and located selectively thereon;
providing a conductive surface proximate to a second surface of the flexible non-conductive substrate;
coupling a plurality of first electrical connections to respective ones of the plurality of conductive plates;
providing a plurality of capacitive flex sensors with the conductive surface, the flexible non-conductive substrate and the plurality of conductive plates, wherein each of said plurality of capacitive flex sensors has a capacitance; and
measuring the capacitance of each of the plurality of capacitive flex sensors.

18. The method according to claim 17, further comprising the step of applying at least one force to at least one area proximate to at least one of said plurality of capacitive flex sensors, whereby at least one capacitance thereof changes.

19. The method according to claim 18, further comprising the step of correlating the measured capacitances of the plurality of capacitive flex sensors with flex forces applied to each of the areas proximate thereto.

20. The method according to claim 19, wherein the flex forces applied represent angular position changes to areas proximate to any one or more of said plurality of capacitive flex sensors.

21. The method according to claim 17, further comprising the step of detecting changes in the measured capacitances.

22. The method according to claim 17, further comprising the step of determining changes in the capacitances of each of said plurality of capacitive flex sensors when the flex forces are applied thereto.
